(19) United States
(12) Patent Application Publication
(10) Pub. No.: US 2016/0133646 A1
(43) Pub. Date: May 12, 2016

(54) ARRAY SUBSTRATE, DISPLAY DEVICE AND REPAIR METHOD OF THE ARRAY SUBSTRATE

(71) Applicants: BOE TECHNOLOGY GROUP CO., LTD., Beijing (CN); BEIJING BOE OPTOELECTRONICS TECHNOLOGY CO., LTD., Beijing (CN)

(72) Inventor: Jian GUO, Beijing (CN)

(21) Appl. No.: 14/386,177

(22) PCT Filed: Jul. 4, 2013
(86) PCT No.: PCT/CN2013/078824

§ 371 Date: Sep. 18, 2014

(30) Foreign Application Priority Data
Mar. 26, 2013 (CN) 201310098734.3

(51) Int. Cl. H01L 27/12

(52) U.S. Cl. CPC H01L 27/124

(57) ABSTRACT

An array substrate, a display device and a repair method of the array substrate. The array substrate may include: a base (1); a gate-line repair line (2) disposed on the base (1); a plurality of data lines (3) disposed over the gate-line repair line (2) and parallel to each other, two ends of each of which have repair sections corresponding to the gate-line repair line (2), respectively; conductive layers (7) disposed on each of the repair sections, respectively, acting to form electric connection between ends of a broken data line and the gate-line repair line (2) after they are melted upon repairing. A gate-line repair line (2) is added, and both ends of a data line (3) have repair sections corresponding to the gate-line repair line (2), respectively, and conductive layers (7) are provided on the repair sections. When the data line is broken off, the data line (3) is connected to the gate-line repair line (2) by melting of the conductive layers (7). Thus, the disconnected data line is connected by the gate-line repair line (2). As compared to prior art, the repair efficiency of the array substrate subjected to cell-assembling is greatly enhanced.

### TECHNICAL FIELD

Embodiments of the present invention relate to an array substrate, a display device and a repair method of the array substrate.

### BACKGROUND

An existing liquid crystal display panel includes a color film substrate and an array substrate that are cell-assembled, and harmful defects will be produced in the course of manufacturing the array substrate. In an existing repair method, connection is made in the place where broken circuit takes place through a chemical vapor deposition conductive layer, or connection is made in the place where broken circuit takes place by means of performing a laser cutting on the position of a broken line and then depositing a conductive layer. In addition, for a place where comparatively serious defects exist and reparation is difficult to be done, it can be repaired based on different modes. In a normally black mode, the bad place is repaired into a black point, and in a normally white mode, the bad place is repaired into a white point.

Drawbacks of the existing technology lie in that, the existing array substrate only can be repaired before cell-assembling, and after the cell-assembling, deposited substances may not reach position of the broken line due to the fact that the array substrate is covered by the color film substrate. Thus, it is hard for the existing array substrate to be repaired after the cell-assembling.

### SUMMARY

According to embodiments of the invention, there are provided an array substrate, a display device and a repair method of the array substrate, capable of enhancing the repair efficiency of the array substrate subjected to cell-assembling.

According to an embodiment of the invention, there is provided an array substrate, comprising: a base; a gate-line repair line disposed on the base; a plurality of data lines disposed over the gate-line repair line and parallel to each other, two ends of each of which have repair sections corresponding to the gate-line repair line, respectively; a gate insulating layer disposed between the gate-line repair line and the data lines, which has first via holes corresponding to the repair sections on a one-to-one basis; conductive layers disposed on each of the repair sections, respectively, which go through hole walls of the first via holes after they are melted upon repairing, so as to form electric connection between ends of a broken data line and the gate-line repair line.

In an embodiment, two ends of each of the data lines may have data line branches, respectively, the repair sections may be located on the data line branches, and the data line branches may have via holes for power-up of the data lines; the array substrate may further include a thin film transistor for allowing conduction of a data line branch, and a gate line connected to the thin film transistor may have a via hole for power-up of the gate line.

In an embodiment, the gate-line repair line may be a closed, frame-like repair line.

In an embodiment, the conductive layers may be of indium tin oxide.

In an embodiment, the repair sections may have second via holes corresponding to the set locations of the conductive layers, and the first via holes of the gate insulating layer may correspond to the set locations of the second via holes on a one-to-one basis.

In an embodiment, the first via holes may lie in a gate insulating layer between the gate-line repair line and the conductive layers.

In an embodiment, the insulating layer may be formed between the conductive layers and a layer of signal lines (such as data lines).

A repair method of any of the array substrates as stated above according to an embodiment of the invention may include:

melting the conductive layers at ends of a broken data line, so that the molten conductive substances go through hole walls of the first via holes to form electric connection between the ends of the broken data line and the gate-line repair line.

In an embodiment, before the conductive layers at both ends of the broken data line are punched through, it further includes breaking off the closed, frame-like gate-line repair line.

In an embodiment, melting the conductive layers may include: melting the conductive layers through laser irradiation.

In an embodiment, melting the conductive layers may include: the gate line and the data line are electrified through a via hole for power-up of the gate line and a via hole for power-up of the data line, and at this time, a thin film transistor connected to the data line branch is turned on, and a conductive layer located on the data line branch is melted.

According to an embodiment of the invention, there is further provided a display device, comprising any of the array substrates as stated above.

According to embodiments of the invention, a gate-line repair line is added, and both ends of a data line have repair sections corresponding to the gate-line repair line, respectively, and conductive layers are provided on the repair sections, respectively. When the data line is broken off, the data line is connected to the gate-line repair line by melting of the conductive layers. Thus, the disconnected data line is reconnected by the gate-line repair line. As compared to prior art, the repair efficiency of the array substrate subjected to cell-assembling is greatly enhanced.

### BRIEF DESCRIPTION OF THE DRAWINGS

FIG. 1 is a structurally schematic view illustrating an array substrate provided by an embodiment of the invention;

FIG. 2 is a schematic view illustrating the repair of an array substrate after a line has been broken off provided by an embodiment of the invention;

FIG. 3 is a structurally schematic view illustrating an array substrate provided by another embodiment of the invention.

### DETAILED DESCRIPTION

In order to enhance the repair efficiency of an array substrate subjected to cell-assembling, an array substrate, a display device and a repair method of the array substrate are provided by the invention. By means of adding a gate-line repair line on the array substrate and adding a conductive layer at two ends of a data line, after disconnection occurs to the data line, connectivity between the data line and the gate repair line is realized by melting of the conductive layer. Thus, the repair efficiency of the array substrate after cell-assembling is enhanced. In order to make objects, technical details and advantages of the invention apparent, hereinafter, the invention will be described in detail further with embodiments as examples.

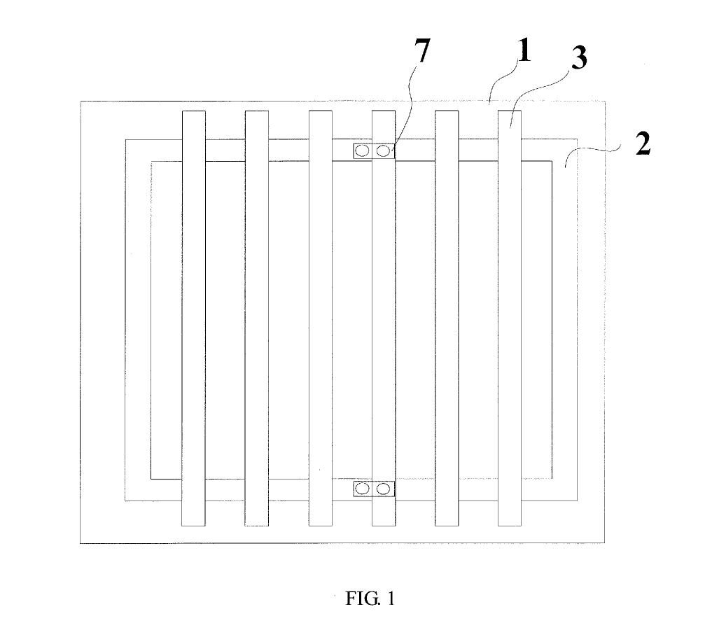

FIG. 1 is a structurally schematic view illustrating an array substrate provided by an embodiment of the invention.

As illustrated in FIG. 1, the array substrate provided by the embodiment of the invention may include: a base 1; a gate-line repair line 2 disposed on the base 1; a plurality of data lines 3 disposed over the gate-line repair line 2 and parallel to each other, for each of which, both ends of it each have a repair section (not illustrated in the figure) corresponding to the gate-line repair line 2; a gate insulating layer (not illustrated in the figure) disposed between the gate-line repair line 2 and the data lines 3, which has first via holes corresponding to repair sections on a one-to-one basis; and a conductive layer 7 disposed on each of the repair sections, separately, which goes through the hole wall of a first via hole after it is melted upon repairing, so as to form the electric connection between an end of a broken data line and the gate-line repair line 2.

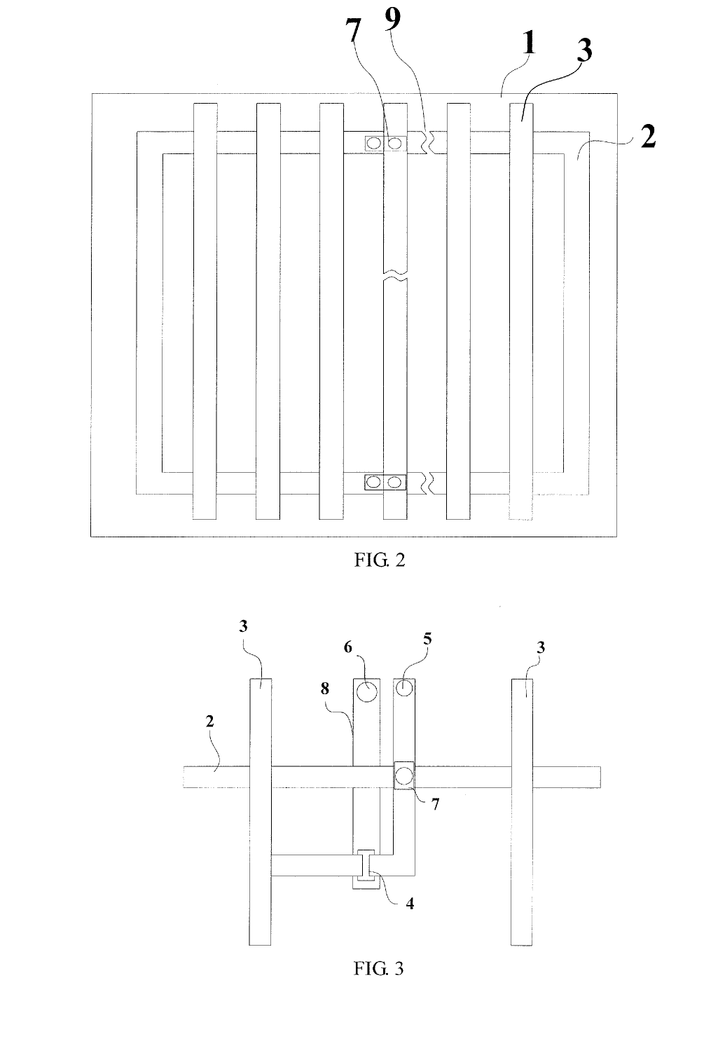

In the above-mentioned embodiment, as illustrated in FIG. 2, when a data line 3 is in operation, a signal is input from one end of the data line 3, and when the data line 3 is broken off, the signal cannot pass through the broken data line. Upon repairing, conductive layers 7 disposed on repair sections at both ends of the data line 3 are melted by laser irradiation, and the molten substances go through first via holes in the gate insulating layer to connect the data line 3 and the gate-line repair line 2. The signal is transferred to the portion of the data line that has been disconnected through the gate-line repair line 2 so that it is present on the whole data line 3. Thus, repair of the broken data line is realized. In the embodiment, a data line 3 is repaired by the added gate-line repair line 2 and conductive layer 7. As the gate-line repair line 2 and the conductive layer 7 have been disposed on the array substrate in the manufacture of the array substrate, there is no need to add conductive substances on the array substrate upon repairing. Therefore, it is possible to carry out repairs conveniently on an array substrate to which disconnection of a data line 3 happens after cell-assembling, and repair efficiency of the array substrate subjected to the cell-assembling is enhanced.

In the above-mentioned embodiment, as an example, the gate-line repair line 2 may be a closed, frame-like repair line. Two data lines 3 that have been broken off can be repaired with the closed gate-line repair line 2. When the closed, frame-like repair line is used to repair data lines 3, it is possible to break up the frame-like data line 3 into two portions at first. As illustrated in FIG. 2, the gate-line repair line 2 is cut off into two portions at the cut-off locations 9 of the gate-line repair line illustrated in FIG. 2, each of the two portions that have been cut off is capable of allowing one of the broken data lines 3 to conduct electricity.

In the above-mentioned embodiment, as illustrated in FIG. 3, as an example, both ends of each data line 3 each have a data line branch, respectively, the repair section may be situated on the data line branch, and there is a via hole 5 for power-up of the data line 3 on the data line branch. The array substrate may further include a thin film transistor 4 for allowing conduction of the data line branch, and on a gate line 8 connected to the thin film transistor 4, there is a via hole 6 for power-up of the gate line. By means of additionally arranging the data line branch on the data line 3, it is possible that by applying electricity to the gate line 8 and the data line 3, the electrified gate line 8 allows the added thin film transistor 4 to turn on, and thus the data line 3 is allowed to conduct electricity. At this time, a conductive layer 7 provided on the data line branch is melted under the thermal action of a current, so as to connect the gate-line repair line and the data line 3. Use of laser irradiation may not be required when such a structure is adopted, so as to reduce repair conditions of the array substrate, and even if a common repair shop can carry out repairs on the array substrate. Furthermore, the repair cost of the array substrate is also be decreased.

In the above-mentioned embodiment, in order to facilitate connection between the gate-line repair line 2 and a data line 3 with a molten conductive layer 7, a first via hole in the gate insulating layer may be chosen to be located at different locations, and producers can make selections depending on different circumstances. For example, a repair section may have a second via hole (not illustrated in the figure) corresponding to the set location of a conductive layer 7, and first via holes of the gate insulating layer may correspond to the set locations of second via holes on a one-to-one basis; and for example, first via holes may lie in a gate insulating layer between the gate-line repair line 2 and the conductive layer 7. The conductive layer 7 can serve to connect the gate-line repair line 2 and a data line 3 through different via holes after it is melted.

In the above-mentioned embodiment, the conductive layer 7 may be a conductive layer 7 with a low melting point. For example, the conductive layer 7 may be indium tin oxide. The melting point of indium tin oxide is relatively low, and is a common material for manufacturing pixel electrodes of thin film transistors in array substrates. Moreover, in an actual manufacturing process, the conductive layer 7 and pixel electrodes may be located within the same plane, and thus, use of indium tin oxide can facilitate formation of the conductive layer 7.

A repair method of an array substrate provided by an embodiment of the invention may include that, a conductive layer at an end of a broken data line is melted, and the molten conductive substances go through the hole wall of a first via hole so as to form electric connection between the end of the broken data line and a gate-line repair line.

A repair method of the array substrate provided by the above embodiment may include the following steps.

101, data lines are detected and a broken data line is determined;

102, the broken data line is powered off;

103, a gate-line repair line is broken off into two portions with laser cutting;

104, conductive layers at two ends of the broken data line are irradiated with laser, so that they are melted and go through hole walls of first via holes and second via holes to form electric connection between the broken data line and the gate-line repair line;

105, the data line that has been repaired is marked, and is subjected to voltage adjustment to let a pixel unit connected to the repaired data line and a pixel unit connected to other data line have the same gray level.

Another repair method of the array substrate provided by the above embodiment may include the following steps.

201, data lines are detected and a broken data line is determined;

202, the broken data line is powered off;

203, a gate-line repair line is broken off into two portions;

204, a gate line and a data line branch are electrified, respectively, the electrified gate line allows an additionally arranged thin film transistor to turn on, so that the data line gets through, and a conductive layer disposed on the data line branch is melted by a current on the data line, and goes through the hole wall of a first via hole after molten to form electric connection between the broken data line and the gate-line repair line;

205, the data line that has been repaired is marked, and is subjected to voltage adjustment to let a pixel unit connected to the repaired data line and a pixel unit connected to other data line have the same gray level.

As can be seen from the above repair methods, with the array substrate provided by embodiments of the invention, it can be repaired conveniently when line breaking happens to it after cell-assembling.

According to an embodiment of the invention, there is further provided a display device, comprising the above array substrate. The display device may be a display panel, an electronic paper, an OLED (Organic Light Emitting Diode) panel, a liquid crystal television, a liquid crystal display, a digital photo frame, a cell phone, a tablet computer or any other product or component having a display function.

Apparently, various modifications and variants of the invention can be made by those skilled in the art without departing from the spirit and scope of the invention. As such, provided that these modifications and variants of the invention fall within the scope of claims of the invention and equivalent technologies thereof, it is also intended to embrace them within the invention.

1. An array substrate, comprising:
a base;
a gate-line repair line disposed on the base;
a plurality of data lines disposed over the gate-line repair line and parallel to each other, two ends of each of which have repair sections corresponding to the gate-line repair line, respectively;
a gate insulating layer disposed between the gate-line repair line and the data lines, which has first via holes corresponding to the repair sections on a one-to-one basis;
conductive layers disposed on each of the repair sections, respectively, which go through hole walls of the first via holes after they are melted upon repairing, so as to form electric connection between ends of a broken data line and the gate-line repair line.

2. The array substrate according to claim 1, wherein two ends of each of the data lines have data line branches, respectively, the repair sections are located on the data line branches, and the data line branches have via holes for power-up of the data lines; the array substrate further includes a thin film transistor for allowing conduction of a data line branch, and a gate line connected to the thin film transistor has a via hole for power-up of the gate line.

3. The array substrate according to claim 2, wherein the gate-line repair line is a closed, frame-like repair line.

4. The array substrate according to claim 3, wherein the conductive layers are of indium tin oxide.

5. The array substrate according to claim 1, wherein the repair sections have second via holes corresponding to set locations of the conductive layers, and the first via holes of the gate insulating layer correspond to set locations of the second via holes on a one-to-one basis.

6. The array substrate according to claim 1, wherein the first via holes lie in the gate insulating layer between the gate-line repair line and the conductive layers.

7. A repair method of an array substrate, the array substrate comprising a base; a gate-line repair line disposed on the base; a plurality of data lines disposed over the gate-line repair line and parallel to each other, two ends of each which have repair sections corresponding to the gate-line repair line, respectively; a gate insulating layer disposed between the gate-line repair line and the data lines, which has first via holes corresponding to the repair sections on a one-to-one basis; conductive layers disposed on each of the repair sections, respectively, which go through hole walls of the first via holes after they are melted upon repairing, so as to form electric connection between ends of a broken data line and the gate-line repair line, wherein, the method comprises:
melting the conductive layers at ends of a broken data line, so that the molten conductive substances go through hole walls of the first via holes to form electric connection between the ends of the broken data line and the gate-line repair line.

8. The repair method of the array substrate according to claim 7, wherein before the conductive layers at both ends of the broken data line are punched through, the method further includes breaking off the closed, frame-like gate-line repair line.

9. The repair method of the array substrate according to claim 8, wherein melting the conductive layers includes: melting the conductive layers through laser irradiation.

10. The repair method of the array substrate according to claim 8, wherein melting the conductive layers includes: the gate line and the data line are electrified through a via hole for power-up of the gate line and a via hole for power-up of the data line, and at this time, a thin film transistor connected to the data line branch is turned on, and a conductive layer located on the data line branch is melted.

11. A display device, comprising the array substrate according to claim 1.

12. The array substrate according to claim 2, wherein the repair sections have second via holes corresponding to set locations of the conductive layers, and the first via holes of the gate insulating layer correspond to set locations of the second via holes on a one-to-one basis.

13. The array substrate according to claim 3, wherein the repair sections have second via holes corresponding to set locations of the conductive layers, and the first via holes of the gate insulating layer correspond to set locations of the second via holes on a one-to-one basis.

14. The array substrate according to claim 45 wherein the repair sections have second via holes corresponding to set locations of the conductive layers, and the first via holes of the gate insulating layer correspond to set locations of the second via holes on a one-to-one basis.

15. The array substrate according to claim 2, wherein the first via holes lie in the gate insulating layer between the gate-line repair line and the conductive layers.

16. The array substrate according to claim 3, wherein the first via holes lie in the gate insulating layer between the gate-line repair line and the conductive layers.

17. The array substrate according to claim 4, wherein the first via holes lie in the gate insulating layer between the gate-line repair line and the conductive layers.

18. The display device according to claim 11, wherein two ends of each of the data lines have data line branches, respectively, the repair sections are located on the data line branches, and the data line branches have via holes for power-up of the data lines; the array substrate further includes a thin film transistor for allowing conduction of a data line branch, and a gate line connected to the thin film transistor has a via hole for power-up of the gate fine.

19. The display device according to claim 11, wherein the gate-line repair line is a closed, frame-like repair line.

20. The display device according to claim 11, wherein the conductive layers are of Indium tin oxide.
